(19) United States
(12) Patent Application Publication
(10) Pub. No.: US 2025/0276449 A1
(43) Pub. Date: Sep. 4, 2025

(54) TASK-SPECIFIC DESIGN OF ROBOTIC MANIPULATORS

(71) Applicant: Amazon Technologies, Inc., Seattle, WA (US)

(72) Inventors: Yuri Anatoly Ivanov, Lexington, MA (US); Allan Zhao, Cambridge, MA (US)

(21) Appl. No.: 18/593,366

(22) Filed: Mar. 1, 2024

(51) Int. Cl. B25J 9/16; G06F 30/20

(52) U.S. Cl. CPC B25J 9/1671; B25J 9/1666; G06F 30/20

(57) ABSTRACT

Techniques for generating robot design specialized for a particular task are described herein. For example, a computer system can receive a first configuration of design parameters for a robotic manipulator that can be used to perform a particular task involving manipulating an object between a set of positions. The design parameters can include discrete hardware parameters. The computer system can set one or more constraints including a waypoint through which the robotic manipulator travels to perform the particular task. The computer system can generate, using an iterative algorithm and based at least in part on the first configuration of design parameters, (i) a second configuration of design parameters and (ii) a trajectory associated with the second configuration for performing the particular task between the set of positions by minimizing an objective function subject to the constraints.

### BACKGROUND

Many modern-day industries are relying more and more on robotic manipulators. Such robotic manipulators may function to increase repeatability of tasks, increase efficiency of production lines, and bring other benefits to their operators. Conventionally, robotic manipulator manufacturers, especially those that develop robotic arms, may offer fixed sizes of robotic arms, leaving little room for customization. This can result in an operator having to pick an oversized, overpowered, and/or otherwise suboptimal robotic arm to perform certain tasks.

### BRIEF DESCRIPTION OF THE DRAWINGS

Various embodiments in accordance with the present disclosure will be described with reference to the drawings, in which:

FIG. 1 illustrates a block diagram and a flowchart showing an example process for generating a robotic manipulator design, according to at least one example;

FIG. 2 illustrates example components of a robot station with a robotic arm performing tasks, according to a particular embodiment;

FIG. 3 illustrates an example revolute joint and an example prismatic joint for a robotic manipulator, according to a particular embodiment;

FIG. 4 illustrates example tasks performed by robotic manipulators, according to a particular embodiment;

FIG. 5 illustrates an example workflow of an iterative algorithm used to design a robotic manipulator, according to an example embodiment;

FIG. 6 illustrates an example design and corresponding trajectory for a robotic manipulator, according to an example embodiment;

FIG. 7 illustrates an example of hyperplane separation used to avoid collisions for a robotic manipulator, according to an example embodiment;

FIG. 8 illustrates an example flow diagram of a process for using the iterative algorithm to generate a design for the robotic manipulator, according to an example embodiment;

FIG. 9 illustrates another example flow diagram of a process for using the iterative algorithm to generate a design for the robotic manipulator, according to an example embodiment; and

FIG. 10 illustrates an environment in which various embodiments can be implemented.

### DETAILED DESCRIPTION

In the following description, various embodiments will be described. For purposes of explanation, specific configurations and details are set forth in order to provide a thorough understanding of the embodiments. However, it will also be apparent to one skilled in the art that the embodiments may be practiced without the specific details. Furthermore, well-known features may be omitted or simplified in order not to obscure the embodiment being described.

Embodiments described herein are directed to, among other things, generating design configurations for a robotic manipulator that is specialized for particular task. A computer system can receive a first configuration of design parameters for a robotic manipulator. The design parameters can include discrete hardware parameters, such as a number or a type of joints in the robotic manipulator. In some examples, the design parameters may also include continuous parameters, such as a length of a segment between joints, mounting angles for joints, a base location for the robotic manipulator, etc. The particular task can involve manipulating an object between a set of positions including a first position and a second position. For example, the set of positions may include a range of start points from which the object may be picked up, as well as a range of end points at which the object may be deposited. The computer system may set constraints for the design of the robotic manipulator, such as setting a waypoint through which the robotic manipulator travels to reach the second position for the particular task. the computer system can use an iterative algorithm to generate a second configuration of design parameters for the robotic manipulator and a trajectory for such a robotic manipulator to traverse to perform the particular task. For example, the computer system can iterate design parameters to minimize an objective function subject to the constraints. The objective function may represent joint torque, cycle time for performing the particular task, maximum velocity of joints while performing the particular task, path length for the trajectory, or any other suitable metric.

To illustrate, consider an example of a fulfillment center. It may be desirable to design a robot that can use a robotic arm and an end effector to perform specialized tasks, such as picking up an object (e.g., a box, a package, or any other type of item) from a conveyer belt and stowing the object in a container (e.g., bin, tote, etc.) associated with an end destination for the object. The specialized task may be dynamic and variable. For dynamic tasks, an inertia and a motion profile (e.g., acceleration and velocity) of the robotic arm can have a significant impact on the performance of the task. A variable task may involve multiple possible start positions and end positions for different objects, as well as continuously variable payloads (e.g., differing sizes or weights of the objects that are manipulated by the robotic arm). The design for such a robotic arm may need to accommodate a wide range of object weights and be able to reach all locations within a workstation. The robotic arm may also need to be designed to avoid obstacles, such as ceilings, pods, bins, etc. This may limit which robot geometries and trajectories are possible for the design.

Designing a robotic arm that can efficiently meet such requirements for a specific task can be a difficult and time-consuming process. Techniques described herein involve a computer system that can generate robotic design parameters with an iterative algorithm. The iterative algorithm can iterate the design parameters to minimize an objective function, while satisfying constraints, to generate a desired design. An initial set of design parameters (e.g., provided by a user) can specify the dimensions of robotic components (e.g., joints and segments connecting the joints), relative mounting angles between the joints, the sequence of joint angles forming trajectories for the robotic arm, and any other hardware design parameters for the robotic arm. The constraints can enforce limitations such as maximum velocity or maximum torque for actuators on the joints, avoiding collisions with nearby obstacles, etc. The objective function can be a quantity to minimize, such as cycle time needed to move the object from a start point to an end point, the torque on the joints, maximum velocity of joints, etc.

The iterative algorithm can start with the initial set of design parameters. In subsequent iterations, the values of the design parameters are adjusted from the initial set until a minimum value for the objective function, and therefore an associated set of design parameters and trajectory, is determined. In some examples, the computer system can use automatic differentiation to find derivatives of constraints and the objective function with respect to the design parameters. This can improve efficiency of the iterative algorithm, which in some examples can generate the robotic arm design for a particular task in less than thirty minutes. Conventional techniques may take weeks or even months to generate a robotic arm design for a specific task.

Embodiments of the present disclosure provide several technological advantages over conventional methods for robotic arm design. For instance, the inclusion of discrete hardware design parameters can enable simultaneous generation of design and trajectory using the iterative algorithm. Conventional techniques may be limited to using continuous hardware parameters and may not take trajectory into account. Additionally, techniques described herein can perform parallel generation of design recommendations across multiple variations of a particular task, such as different start positions and end positions or different object sizes. The trajectory for each variant may differ but the hardware design parameters may be shared. This can allow for design of a robotic arm that can perform well on average for an entire task variant distribution. Further, conventional techniques, such as k-order Markov models, may not specify a method for avoiding collisions. Techniques described herein involve using hyperplane separation theorem to reliably prevent generation of trajectories that tunnel through obstacles. Such an approach is continuously differentiable and therefore compatible with automatic differentiation and gradient-based optimization.

In the interest of clarity of explanation, embodiments described herein in connection with an inventory system, inventory items (e.g., items associated with an inventory), and manipulations related to an inventory. However, the embodiments are not limited as such. Instead, the embodiments may similarly apply to any objects, whether inventoried or not, and to any system, whether related to inventorying objects or not. For example, the embodiments may similarly apply to a manufacturing system, supply chain distribution center, airport luggage system, or other systems using robot stations to perform various automated, and, in some instances, autonomous operations.

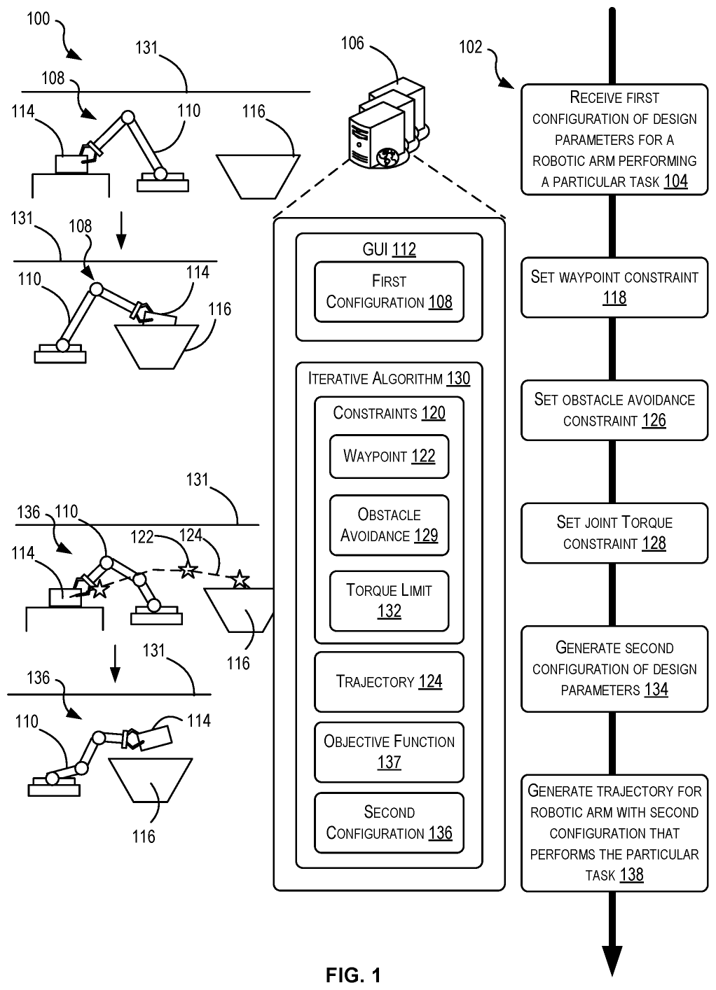

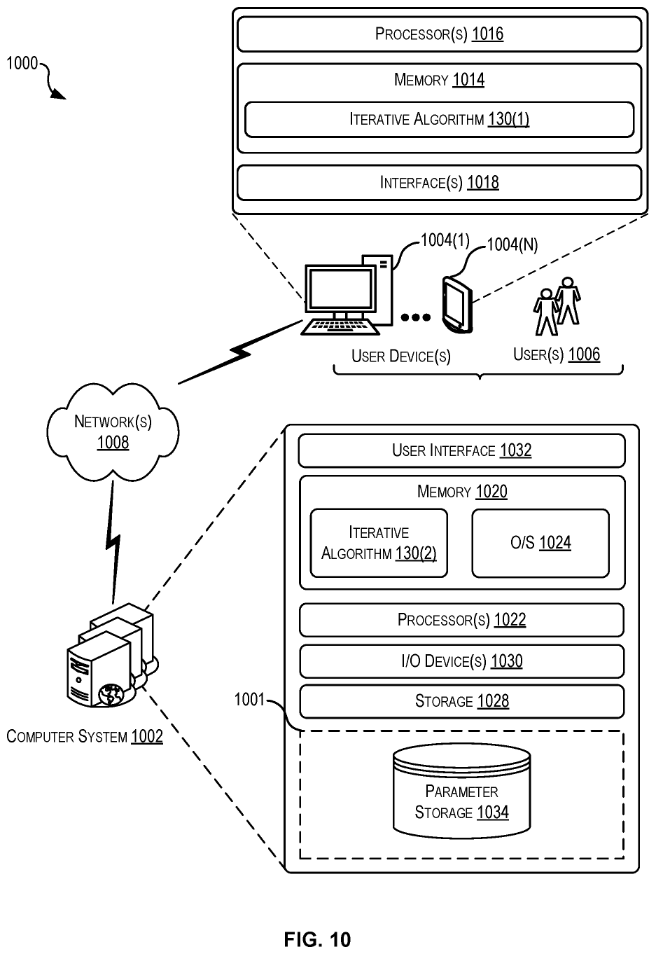

FIG. 1 illustrates a block diagram 100 and a flowchart showing an example process 102 for generating a robotic manipulator design, according to at least one example. The diagram 100 depicts devices, objects, and the like that correspond to the process 102. The process 102 can be performed by any suitable combination of hardware and/or software as implemented by a computer system, such as computer system 106, the computer system 1002 of FIG. 10, or any other suitable device. The computer system 106 and the computer system 1002 may be any suitable combination of computing devices such as one or more server computers, which may include virtual resources, services, and the like capable of performing the functions described with respect to the computer system 106 or the computer system 1002. In some examples, components of the computer system 106 or the computer system 1002 may be distributed between a server (e.g., a cloud-based virtual instance) and a local computer.

FIGS. 1, 8, and 9 illustrate example flow diagrams showing processes 102, 800, and 900 according to at least a few examples. Some or all of the process 102, 800, and 900 (or any other processes described herein, or variations, and/or combinations thereof) may be performed under the control of one or more computer systems configured with executable instructions and may be implemented as code (e.g., executable instructions, one or more computer programs, or one or more applications) executing collectively on one or more processors, by hardware or combinations thereof. The code may be stored on a computer-readable storage medium, for example, in the form of a computer program comprising a plurality of instructions executable by one or more processors. The computer-readable storage medium may be non-transitory.

The process 102 may begin at block 104 by the computer system 106 receiving a first configuration 108 of design parameters for a robotic arm 110 to perform a particular task. For example, the first configuration 108 may be input by a user into a graphical user interface (GUI) 112 presented by the computer system 106. The first configuration 108 can be a starting point used to generate a recommended design for the robotic arm 110. For example, the first configuration 108 may include discrete hardware parameters such as a number of joints (e.g., two) and a type of joint (e.g., revolute) and continuous hardware parameters such as a length of segments between joints, a mounting angle for the joints, etc. The first configuration 108 can also include the particular task that is to be performed by the robotic arm 110. In the example depicted in FIG. 1, the particular task can involve moving an object 114 (e.g., a box) from a first position (e.g., on a conveyer belt) to a second position (e.g., into a bin 116). In some examples, the particular task may involve moving the object 114 from any of a first set of positions to any of a second set of positions, as objects may be picked up from or stowed into boxes of differing locations.

At block 118, the computer system 106 can set constraints 120 for designing a robotic arm, including waypoint 122. The waypoint 122 can be a point along a trajectory 124 for the robotic arm 110 that the robotic arm 110 passes through in order to reach the second position (e.g., placing the object 114 into the bin 116). Setting a waypoint 122 as a constraint can help prevent generating a robotic arm 110 with a trajectory 124 that intersects with obstacles, such as the side of the bin 116. For example, the waypoint 122 can be set to cause a trajectory 124 in which the robotic arm 110 lifts the object 114 above the bin 116 before placing the object 114 into the bin 116. This can prevent the robotic arm 110 from attempting to place the object 114 into the bin 116 through the sides of the bin 116.

At block 126, the computer system 106 can set a constraint for obstacle avoidance 129 by specifying a set of points associated with an obstacle, such as the ceiling 131. This set of points can be used according to hyperplane separation theorem to prevent the computer system 106 from generating a trajectory 124 that intersects with the ceiling 131. For example, the computer system 106 can generate a first set of inequality constraints for each segment (e.g., connecting link between adjacent joints) of the robotic arm 110 and a second set of inequality constraints representing corners of the area of ceiling 131 that can be contacted by the robotic arm 110. The sets of inequality constraints can be used to generate an optimally separating hyperplane that separates two convex hulls of points and is equidistant from the two.

At block 128, the computer system 106 can set a constraint of a torque limit 132 for the robotic arm 110. The torque limit 132 can be a maximum torque that any single joint in the robotic arm 110 experiences while performing the particular task (e.g., manipulating the position of the object 114 along the trajectory 124). Combinations of design parameters that result in joint torque that exceeds the torque limit 132 may be discarded.

At block 134, the computer system 106 can use the iterative algorithm 130 to generate a second configuration 136 of design parameters for the robotic arm 110 by minimizing an objective function 137 subject to the constraints 120 based on the first configuration 108 of design parameters. The objective function 137 can define one or more features that are beneficial to minimize for the robotic arm 110, such as cycle time for performing the particular task, torque applied to the joints while performing the particular task, number of joints, range of motion while performing the particular task, or any other suitable feature that would be desirable to minimize in a robotic arm 10. The computer system 106 can minimize the objective function 137 by performing multiple iterations of combinations of design parameters that are adjusted from the first configuration 108 of design parameters and that meet the constraints 120. The iteration with the lowest value for the objective function 137 can be selected as the second configuration 136 of design parameters.

The second configuration 136 of design parameters can more efficiently perform the particular task (e.g., with respect to the objective function 137) than the first configuration 108 of design parameters. For example, constraints 120 such as a low height for the ceiling 131 may cause difficulties or increase cycle time for a robotic arm 110 that has the first configuration 108 of design parameters. But a robotic arm 110 with the second configuration 136 of design parameters, including three joints instead of two joints, may perform the particular task faster and with less risk of collision with the ceiling 131 than a robotic arm 110 with the first configuration 108 of design parameters.

At block 138, the computer system 106 can use the iterative algorithm 130 to generate one or more trajectories 124 associated with the second configuration 136 and used to move the object 114 as part of the particular task (e.g., from any of the first set of positions to any of the second set of positions). The trajectory 124 and the second configuration 136 can be determined together (e.g., substantially simultaneously), as possible trajectories 124 are limited by the geometry of the hardware design for the robotic arm 110. The trajectory 124 may also be determined by minimizing the objective function 137 subject to the constraints 120. For example, for every iteration of adjusted design parameters, the computer system 106 may test potential trajectories that can start from any of a set of start positions (e.g., locations along a conveyer belt) and end in any of a set of end positions (e.g., bins located at different heights), subject to constraints 120 (e.g., passing through the waypoint 122 or avoiding obstacles such as the ceiling 131). In such examples, the objective function may define trajectory features such as change in joint position. The second configuration 136 of design parameters may be selected based on having trajectories 124 that best minimizes the objective function 137 on average for its iteration of design parameters.

After selection, the computer system 106 can output the second configuration 136 and associated trajectories 124 for use in producing a robot according to the second configuration 136. For example, the computer system 106 may cause the GUI 112 to display the second configuration 136 and the trajectories 124. In some examples, a user may input additional constraints, adjustments to the second configuration 136, adjustments to the objective function 137, etc. for use in subsequent rounds of iteration by the computer system 106 (e.g., to produce a third configuration of design parameters that improves upon the second configuration 136 with respect to the objective function 137).

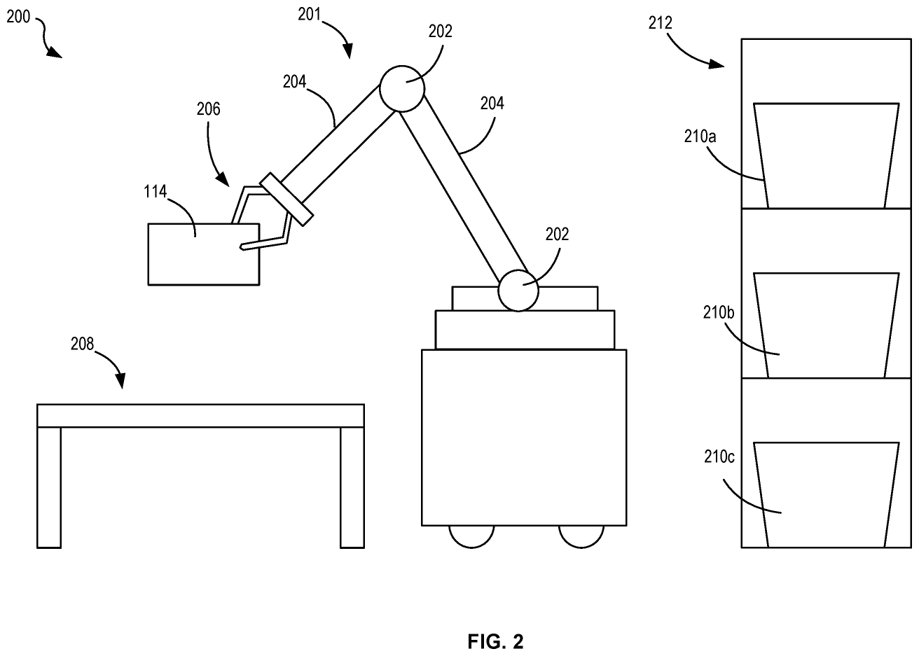

FIG. 2 illustrates example components of a robot station 200 with a robotic manipulator 201 (e.g., a robotic arm) performing tasks, according to a particular embodiment. In some examples, the robot station 200 may be an inventory station in an inventory management system. The robotic manipulator 201 can perform tasks relating to inventorying objects 114. These tasks may include manipulating the objects 114. To manipulate an object 114, the robotic manipulator 201 may include one or more joints 202, one or more segments 204 connecting adjacent joints 202, and an end effector 206 that can grasp the object 114. A manipulation of an object 114 may represent a set of actions applied to the object 114 in association with an inventory task. For example, the object 114 may be received from a source external to the inventory management system, such as from a manufacturing facility or a distributing facility. The object 114 may arrive to the inventory management system and may be delivered to the robotic manipulator 201 by way of a conveyer belt 208 or some other delivery mechanism. The robotic manipulator 201 may stow the item by, for example, grasping, moving, and releasing the item into a container, such as first container 210a, second container 210b, or third container 210c. The containers 210a-c may be located in an inventory holder 212. Grasping, moving, and releasing an object 114 may represent examples of manipulations applied to the object 114. Conversely, the same or different robot station 200 may stow the object 114 from the inventory holder 212 in preparation for a delivery of the object 114 to a destination. The respective robot station 200 may use a robotic manipulator to pick the container 210, grasp and move the object 114 from the container 210, package the object 114, and place the package on the conveyer belt 208. Picking, packaging, and placing may represent other examples of manipulation. Once on the conveyer belt 208 again, the package may be moved to a delivery vehicle for delivery.

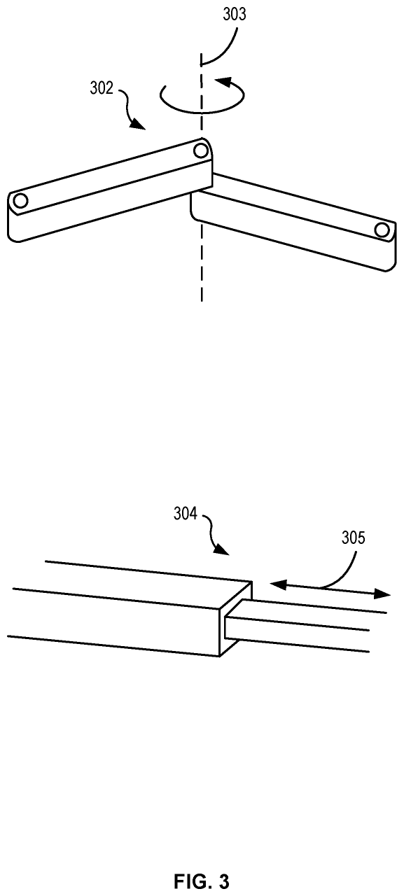

The robot station 200 may be used to perform the same task or task variant. Thus, it may be beneficial to design a robotic manipulator 201 that is specialized for that task or task variant and for the features present in the robot station 200. The computer system 106 of FIG. 1 can use the iterative algorithm 130 to generate a configuration of design parameters that can avoid obstacles, such as the conveyer belt 208, walls of the inventory holder 212 or the containers 210a-b, and reduce time involved in moving objects 114 from the conveyer belt 208 to the containers 210a-c or vice versa. The design parameters can include any combination of discrete or continuous hardware parameters. For example, as depicted in FIG. 3, the design parameters can include revolute joints 302 and prismatic joints 304. The revolute joint 302 can have one degree of freedom (e.g., around the z axis 303) and can allow a robotic manipulator to rotate in different directions, as depicted in FIG. 3. The prismatic joint 304 (e.g., a linear joint) can also have one degree of freedom and can cause a sliding motion of a robotic manipulator (e.g., along the z axis 305), such as along a horizontal direction as depicted in FIG. 3. The design parameters can also include a length of the segment 204 of a robotic manipulator, such as a segment 204 connecting two revolute joints 302. Although two types of joints are depicted, any suitable type of joint may be selected by the computer system 106 as a design parameter for the robotic manipulator. Each component of the robotic manipulator may be customizable in selection and combination.

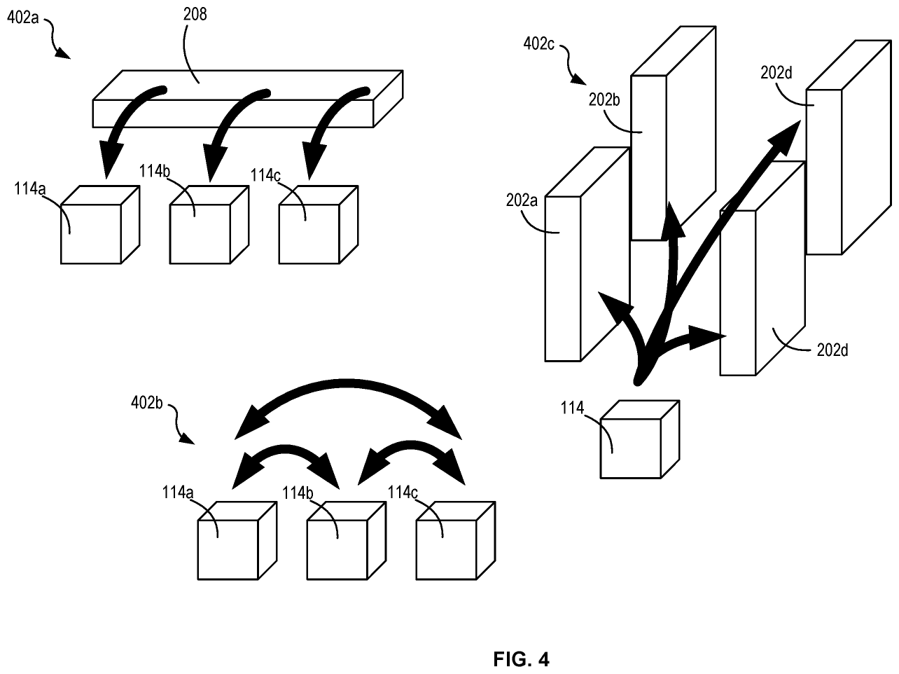

FIG. 4 illustrates example tasks 402a-c performed by robotic manipulators, according to a particular embodiment. The computer system 106 of FIG. 1 may determine the second configuration 136 of design parameters for the robotic manipulator based on the task 402a-c performed by the robotic manipulator. For example, a first task 402a may involve a robotic manipulator grabbing objects 114a-c off from a source (e.g., conveyer belt 208) and moving the objects 114a-c to a different destination. Different objects may have different destinations, and the robotic manipulator may pick up the objects 114a-c along various points of the conveyer belt 208. Thus, the computer system 106 can set constraints based on the first task 402a that require the design parameters for the robotic manipulator to allow for trajectories that can access a range of start points (e.g., locations on the conveyer belt 208 from which objects 114a-c can be grabbed) and a range of end points (e.g., locations of destinations for the objects 114a-c).

In another example, a second task 402b can involve the robotic manipulator sorting objects 114a-c or otherwise manipulating the position of objects 114a-c. Similar to the first task 402a, the computer system 106 can set constraints that require the design parameters for the robotic manipulator to allow for trajectories that can access any position to which a particular object 114 may be placed while sorting. In a further example, a third task 402c can involve the robotic manipulator stowing an object 114 in one of several inventory holders 202a-d. The computer system 106 can set constraints that require the design parameter for the robotic manipulator to allow for trajectories that include end points at locations of all of the inventory holders 202a-d.

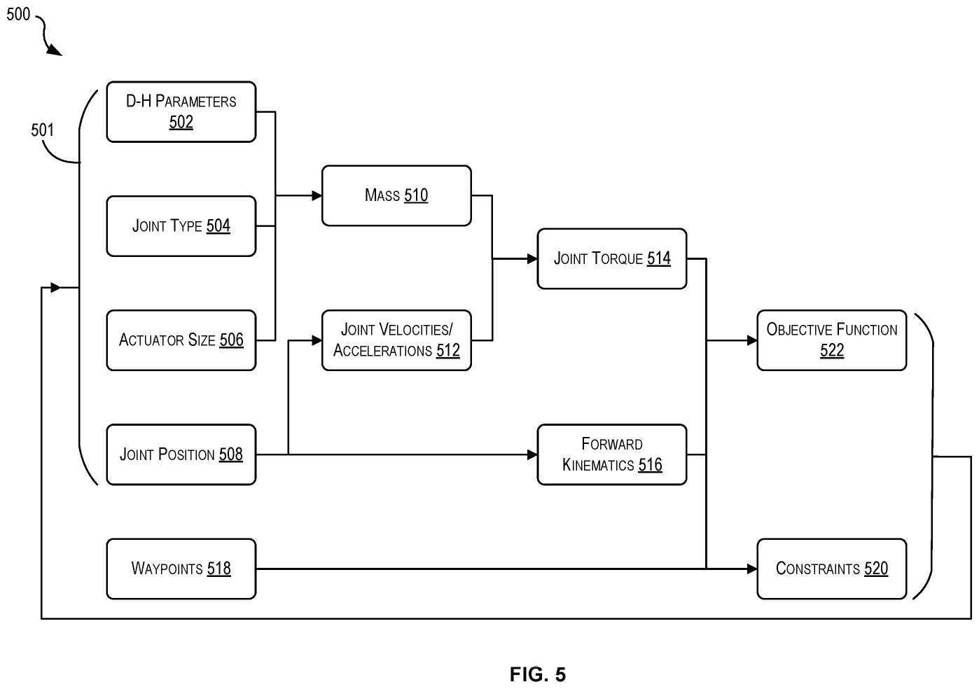

FIG. 5 illustrates an example data flow 500 of an iterative algorithm used to design a robotic manipulator, according to an example embodiment. The operations of the example data flow 500 can be performed by any suitable computer system, including computer system 106 of FIG. 1. The data flow 500 can begin with the computer system 106 receiving or setting design parameters 501 for the robotic manipulator. The design parameters 501 can be hardware parameters such as Denavit-Hartenberg (D-H) parameters 502 (e.g., segment length and mounting angles for joints), joint type 504 (e.g., revolute joints or prismatic joints), actuator size 506, sequence of joint positions 408 in a trajectory for the robotic manipulator, and any other suitable hardware parameter. Some of the design parameters 501, such as D-H parameters 502 and joint position 508, can be continuous hardware parameters (e.g., can be any value along a range of values). Another example of a continuous hardware parameter can include a base location for the robotic manipulator. Other design parameters 501, such as joint type 504 and actuator size 506, can be discrete hardware parameters. Another example of a discrete hardware parameter can include a number of degrees of freedom for the robotic manipulator or, in other words, a number of joints in the robotic manipulator.

The computer system 106 can iterate on the design parameters 501 to produce a recommended set of design parameters. After setting an initial set of design parameters 501, the computer system 106 can determine an impact of mass 510 and joint velocities and accelerations 512 for the initial set of design parameters 501. For example, the computer system 106 can the joint velocities and accelerations 512 involved in such a robotic manipulator manipulating an object with a particular mass 510 (e.g., the velocities and accelerations that are caused by the actuators for the joints). The computer system 106 can also determine a maximum joint torque 514 on each of the joints while performing the particular task with an object having the mass 510. The computer system 106 may also determine forward kinematics 516 for such a robotic manipulator, which can involve an end acceleration and an end velocity for the robotic manipulator when reaching the end point of a trajectory.

In some examples, these values may not meet constraints 520 required for the robotic manipulator. The constraints 520 can ensure a valid solution to the task. One example of a constraint 520 can be a waypoint through which the robotic manipulator must travel through to reach an end point of a trajectory. Other constraints can include maximum joint velocities and accelerations, torque limits on the joints, setting the end velocity and end acceleration to be zero, avoiding nearby obstacles, or any other suitable constraints. If the current iteration of design parameters 501 produces a robotic manipulator that does not meet the constraints 520 (e.g., maximum torque exceeds torque limits), the current iteration may be discarded and a new iteration of design parameters 501 may be generated.

If the current iteration of design parameters 501 meets the constraints 520, the computer system 106 can determine an objective function 522 for the current iteration. The objective function 522 can represent a feature of the robotic manipulator that may be desirable to minimize. One example of an objective function 522 representing joint torque can be f(x)=Σ_{k-1 . . . N}||τₖ(x)||₂². Such an objective function 522 can minimize the sum of squared torques on each joint. This can aid in identifying design parameters with trajectories that have relatively smooth acceleration at the start and end of the trajectory. Another example of an objective function 522 representing lower cycle time to perform a particular task can be f(x)=Δt. In some examples, the objective function 522 can represent a number of changes in joint position. Minimizing such an objective function 522 can minimize an amount of energy (e.g., applied by an actuator for the joint) and time involved in performing a task.

In some examples, the computer system 106 may additionally determine multi-path optimization for a current iteration of design parameters 501. For example, a task may have multiple task variants that may involve multiple potential start points and end points. Thus, it may be beneficial for a robotic manipulator to perform multiple different trajectories to accomplish variants of the task. For each iteration of design parameters 501, iterations of trajectories can be tested. That is, the hardware of the design parameters 501 can be constant while the trajectory can be varied by testing different trajectories with differing start points and end points. In some examples, all possible trajectories can be tested. In other examples, a set of randomly sampled trajectories can be tested, as there may only be a few simultaneous trajectories that are possible. The computer system 106 can generate a value for the objective function for each iteration of trajectory. In examples with multi-path optimization, the value of the objective function 522 for the current iteration of design parameters 501 as a whole may be an average of the values of the objective functions determined from all of the trajectories tested with the current iteration of design parameters 501. That is, the value for the objective function 522 for the current iteration of design parameters 501 can represent an average performance of the current iteration across possible trajectories for task variants. In a similar manner, each iteration of design parameters 501 can be tested with differing payloads (e.g., size or mass of the object that is manipulated by the robotic manipulator). The value of the objective function 522 for the current iteration of design parameters 501 as a whole may be an average of the values of the objective functions determined from the different payloads tested with the current iteration of design parameters 501.

After determining the objective function 522 for the current iteration of design parameters 501, the computer system 106 can restart the data flow 500 by adjusting the values of the design parameters 501 for a new iteration. After all valid iterations (e.g., that meet constraints 520) for the iterative algorithm have been generated, the computer system 106 can determine the objective function 522 with the lowest calculated value. The iteration of design parameters 501 associated with this lowest value of the objective function 522 can be selected as the final set of design parameters 501 that is recommended for the particular task and the constraints 520. In some examples, the computer system 106 may perform additional rounds of optimization using the iterative algorithm. For example, a different initial set of design parameters may be provided, constraints 520 may be added or adjusted, etc.

In some examples, the computer system 106 may use the iterative algorithm to generate

a design of the robotic manipulator that is specialized to perform two realistic tasks. The first task can be a more general task, such as the ability to reach randomly selected positions in the robot station. The second task can be a more specialized task, such as picking an object to stow in a container, scanning an object with a barcode scanner held by an end effector of the robotic manipulator, etc. Resulting recommended design parameters may have improved (e.g., reduced) joint torque compared to design parameters selected for only a general task or a specialized task.

In some examples, automatic differentiation can be used to find derivatives of constraints 520 and the objective function 522 with respect to the design parameters 501. This can be used to minimize the objective function 522 when the iterative algorithm includes both discrete hardware parameters and continuous hardware parameters. In order to simultaneously determine a recommended design that addresses both types of parameters, the objective function 522 can be constructed to cause a derivative of the objective function 522 to peak at discrete values. This can drive the value of a hardware design parameter to be limited to those discrete values, such as 1 (representing revolute joints) and 2 (representing prismatic joints), a discrete number of joints, etc.

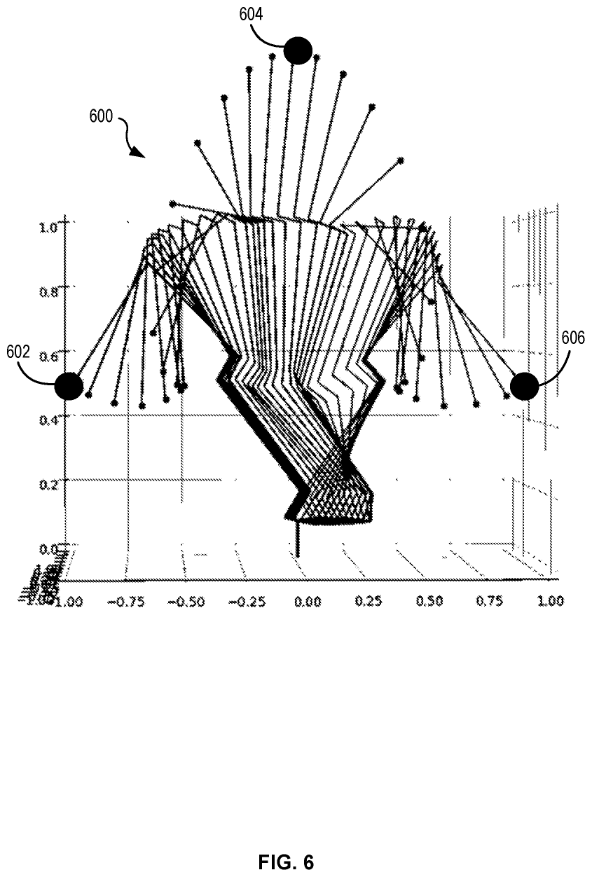

FIG. 6 illustrates an example design and corresponding trajectory 600 for a robotic manipulator, according to an example embodiment. The design and trajectory 600 can be generated by the computer system 106 using the iterative algorithm. The trajectory 600 of FIG. 6 depicts the positioning of the robotic manipulator as the robotic manipulator moves from a first position 602, through a waypoint 604, and to a second position 606. The robotic manipulator can move positions by changing joint angles. The example depicted in FIG. 6 includes six joints, but any number and combination of joints can be used. Each straight line segment in the design can represent a segment of the robotic manipulator attached to one or more joints.

Inserting a waypoint 604 as a constraint for the trajectory 600 can allow for design of robotic arms that can perform complicated tasks. In some examples, insertion of the waypoint 604 as a constraint can aid or be a workaround for preventing obstacle collision. For example, the waypoint 604 may be included in the trajectory 600 to cause the robotic manipulator to lift an object over an edge of a container in order to deposit the object into the container.

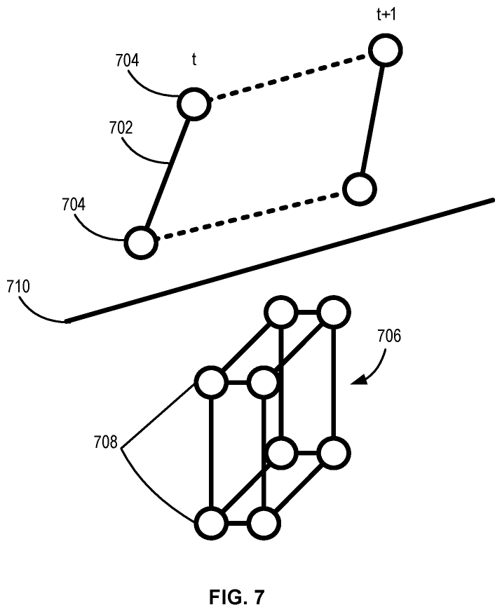

FIG. 7 illustrates an example of hyperplane separation used to avoid collisions for a robotic manipulator, according to an example embodiment. Hyperplane separation theorem involves determining an optimal hyperplane between two closed sets, where one of the sets is complex. In some examples, the computer system 106 of FIG. 1 can set use the hyperplane separation theorem to identify an optimal hyperplane between the robotic manipulator and an obstacle, such as a ceiling, conveyer belt, side of a container, etc. The trajectory can include the optimal hyperplane to prevent obstacle collision.

For example, the computer system 106 may set inequality constraints in the iterative algorithm to determine an optimal hyperplane 710. For each pair of a segment 702 in the robotic manipulator and an obstacle 706, the computer system may set one or more inequality constraints. Inequality constraints for the segment 702 can dictate that the ends 704 of the segment 702 in both time t and subsequent time t+1 are on a positive side of an optimal hyperplane 710. Inequality constraints for the obstacle 706 can dictate that corners 708 of the obstacle 706 are on a negative side of the plane. If all such planes exist, there may not be a possibility of collision. If one or more planes exist, such an optimal hyperplane may be incorporated into the trajectory to avoid collision with obstacles. The inequality constraints for the segment 702 or the obstacle 706 can be continuously differentiable, which can be compatible with automatic differentiation and gradient-based optimization that may be used to minimize the objective function.

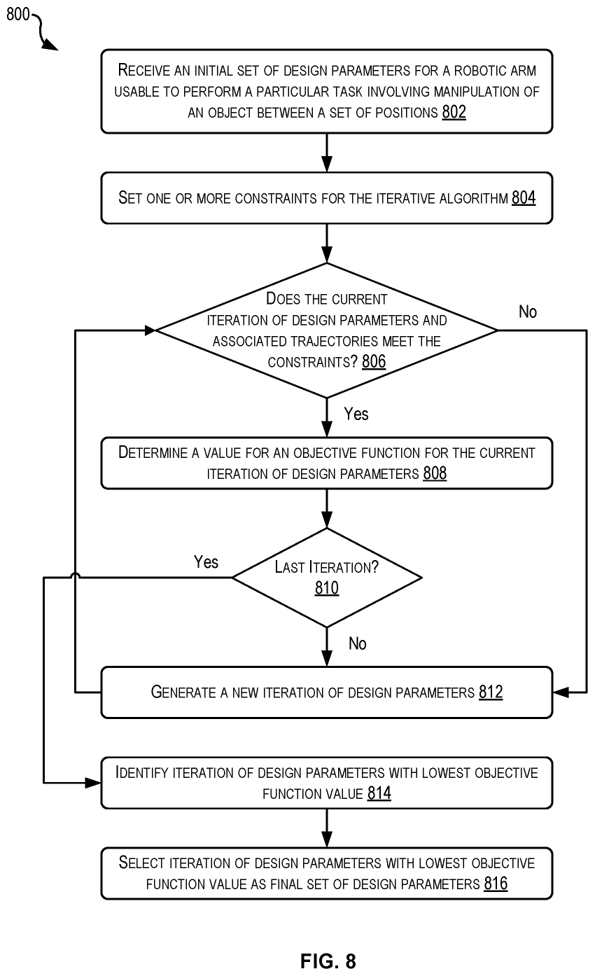

FIG. 8 illustrates an example flow diagram of a process 800 for using the iterative algorithm to generate a design for the robotic manipulator, according to an example embodiment. In some examples, the computer system 106 of FIG. 1 or the computer system 1002 of FIG. 10 may perform some or all parts of the process 800.

The process 800 begins at block 802 by receiving an initial set of design parameters for a robotic arm that can be used to perform a particular task involving manipulation of an object between a set of positions, including a first position and a second position. For example, the particular task may involve moving a robotic arm that is grasping a barcode scanner to a position near an item, so that the barcode scanner can scan a barcode on the item. The start point and end point may vary depending on where the item or the robotic arm is initially located, so the particular task may involve a range of start points and a range of end points in the set of positions. The initial set of design parameters may be provided by a user and may be a starting point for an iterative algorithm to generate an improved design (e.g., a final set of design parameters) for a robotic arm that is specialized for the particular task. In this example, the initial set of design parameters may include one prismatic joint at a base of the robotic arm and six revolute joints between the prismatic joint and an end effector that can grasp the barcode scanner. But, other numbers and types of joints (as well as any other hardware parameters, such as segment length, mounting angle, actuator size, base location, etc.) may be combined to create an improved robotic arm (e.g., that can perform the particular task faster, with less joint torque, less joint position changes, etc.). The initial set of design parameters can be a first iteration of design parameters used by the iterative algorithm.

At block 804, the process 800 involves setting one or more constraints for the iterative algorithm. The constraints can place limits on what values of design parameters can be combined to generate a robotic arm that is able to perform the particular task. For example, the constraints can include torque limits or limits on a number of joint position changes in a trajectory, in order to prevent the iterative algorithm from generating robot designs with complicated and unrealistic trajectories. Setting torque limits can also constrain the iterative algorithm to selecting relatively smaller actuator sizes for the joints. Additional constraints can include waypoints through which the trajectory must travel, or obstacles through which the trajectory does not intersect (e.g., to prevent collisions).

At block 806, the process 800 involves determining if the current iteration of design parameters and its associated trajectories meet the constraints. If the current iteration is the first iteration, the current iteration can be the initial set of design parameters. The computer system can determine if the current iteration of design parameters and its associated trajectories meets the constraints by modeling performance of a robotic arm that has the current iteration of design parameters. For example, the computer system can test joint torque performance for such a robotic arm that is manipulating objects of a range of sizes. Or, the computer system can test such a robot arm traversing multiple combinations of trajectories while performing the task.

If the current iteration of design parameters meets the constraints (e.g., the performance of the modeled robotic arm does not exceed limits placed by the constraints), the process 800 can continue to block 808. If the current iteration of design parameters does not meet the constraints (e.g., the computer system determines invalid results for the modeled robotic arm due to falling outside limits set by the constraints), the process 800 can continue to block 812.

At block 808, the process 800 involves determining a value for an objective function for the current iteration of design parameters. The objective function can define one or more features that may be desirable to minimize for the robotic arm. For example, the objective function may define a maximum torque on any of the joints in the robotic arm. In other examples, the objective function may define a minimum cycle time involved in performing the particular task (e.g., moving the robotic arm from an initial position to an end position that positions a barcode scanner held by the robotic arm above a barcode on an item for scanning). In some examples, the computer system may generate multiple objective values for the current iteration and determine an average objective value to represent the current iteration. For example, the computer system may determine an objective value for each sub-iteration that tests a robotic manipulator having the design parameters and manipulating objects along a range of sizes, or for each sub-iteration of multiple trajectories performed by a robotic manipulator that has the design parameters. The average value of the objective functions determined for all of the sub-iterations can be the value of the objective function for the current iteration of design parameters.

At block 810, the process 800 involves determining whether the current iteration of design parameters is the last iteration performed by the iterative algorithm. If the current iteration is the last iteration, the process 800 can continue to block 814. If the current iteration is not the last iteration, the process 800 can continue to block 812.

At block 812, the process 800 involves generating a new iteration of design parameters. The new iteration of design parameters can have values that are adjusted from the previous iteration of design parameters to create a new and unique combination of parameters that have not yet been tested. The process 800 can then continue to block 806, where the iterative algorithm can continue generating an objective value for each iteration until all iterations have been tested.

At block 814, the process 800 involves identifying the iteration of design parameters with the lowest objective function value. In other words, the iterative algorithm can minimize the objective function subject to the one or more constraints. The iteration of design parameters with the lowest objective function value may be the combination of design parameters that is best suited for performing the particular task, even along a range of start points and end points or for objects with a range of masses. At block 816, the process 800 involves selecting the iteration of design parameters with the lowest objective function value as the final set of design parameters. The final set of design parameters can be output (e.g., for display on a graphical user interface) for use in generating a specialized robotic arm.

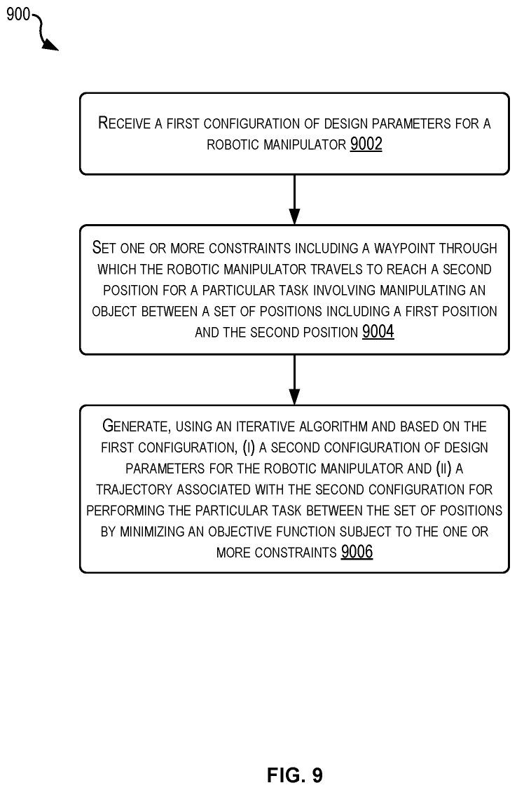

FIG. 9 illustrates another example flow diagram of a process 900 for using the iterative algorithm to generate a design for the robotic manipulator, according to an example embodiment. In some examples, the computer system 106 of FIG. 1 or the computer system 1002 of FIG. 10 may perform some or all parts of the process 900.

The process 900 begins at block 902 by receiving a first configuration of design parameters for a robotic manipulator. In some examples, a robotic manipulator that has the first configuration of design parameters may be able to perform a particular task involving manipulating an object between a set of positions including a first position and a second position. In other examples, the first configuration of design parameters may be randomly generated. In some examples, the set of positions can include a first set of positions and a second set of positions. The iterative algorithm may be used to determine trajectories of a robotic manipulator between any of a first set of positions (including the first position) and any of the second set of positions (including the second position). The design parameters can include one or more discrete hardware parameters. Examples of discrete hardware parameters can include a type of joint, such as a revolute joint or a prismatic joint, a number of joints, or an actuator size for a joint in the robotic manipulator. In some examples, the design parameters may also include one or more continuous hardware parameters. Examples of continuous hardware parameters can include a segment length between adjacent joints, a joint mounting angle, or a base location for the robotic arm. In some examples, the first configuration of design parameters may be for a component of the robotic manipulator. That is, design parameters other components of the robotic manipulator may be held constant, and the iterative algorithm may only iterate on values of hardware design parameters for the component of the robotic manipulator.

At block 904, the process 900 involves setting one or more constraints including a waypoint through which the robotic manipulator travels to reach the second position for the particular task that involves manipulating the object between the set of positions including the first position and the second position. In some examples, the one or more constraints can additionally include a set of points associated with an obstacle through which the robotic manipulator is prevented from traveling. This can ensure that a trajectory generated for the robotic manipulator does not intersect with the set of points associated with the obstacle. Further constraints can include a torque limit for one or more joints of the robotic manipulator, an end velocity and an end acceleration of zero at an end point of the trajectory, etc.

At block 906, the process 900 involves generating, using an iterative algorithm and based at least in part on the first configuration of design parameters, (i) a second configuration of design parameters for the robotic manipulator and (ii) a trajectory associated with the second configuration for performing the particular task between the set of positions by minimizing an objective function subject to the one or more constraints. In some examples, the iterative algorithm can generate the second configuration of design parameters simultaneously with the trajectory. This is because the design of the robotic manipulator may determine possible trajectories for the robotic manipulator, and vice versa. In some examples, the objective function can include a cycle time for the robotic manipulator to move the object from the start point to the end point along the trajectory, or from any of the first set of positions to any of the second set of positions along the trajectory. In some examples, the objective function may additionally or alternatively include a sum of squared torques on the one or more joints when performing the particular task.

In some examples, generating the second configuration of design parameters and the trajectory can first involve generating a set of adjusted design parameters that satisfy the one or more constraints by iterating on the first configuration of design parameters. For example, each adjusted design parameter in the set of adjusted design parameter can have a unique combination of values for the design parameters. The computer system can determine a value of the objective function for each of the set of adjusted design parameters to generate a set of values. The second configuration of design parameters can be selected by identifying an adjusted design parameter that is associated with a minimum value from the set of values.

In some examples, for each combination of adjusted design parameters of the set of adjusted design parameters, the computer system can determine a value of an objective function based on each combination of a start point of a range of start points in the set of positions and an end point of a range of end points in the set of positions for the robotic manipulator performing the particular task. By doing so, the computer system can generate another set of values for the objective function (e.g., one for each combination of start point and end point). The second configuration of design parameters can additionally be selected based on identifying a minimum value of the other set of values for the objective function. In some examples, the computer system can determine an average value of the set of values for the objective function. The computer system can select the second configuration of design parameters by determining that the second configuration is associated with a lowest average value for the objective function of the set of adjusted design parameters.

In some examples, for each combination of design parameters of the set of adjusted design parameters, the computer system can determine the value of the objective function based on each mass of a set of masses for the object. Doing so can generate a set of values of the objective function for the combination. The computer system can select the second configuration of design parameters by determining that the second configuration is associated with a lowest average value for the objective function of the set of adjusted design parameters.

FIG. 10 illustrates aspects of an example environment 1000 for implementing aspects in accordance with various embodiments. The environment 1000 may include a computer system 1002 (e.g., the computer system 106 described herein) in communication with one or more user devices 1004(1)-1004(N) via one or more networks 1008 (hereinafter, “the network 1008”).

The user device 1004 may be operable by one or more users 1004 to interact with the computer system 1002. The user device 1004 may be any suitable type of computing device such as, but not limited to, a tablet, a mobile phone, a smart phone, a network-enabled streaming device (a high-definition multimedia interface (“HDMI”) micro-console pluggable device), a personal digital assistant (“PDA”), an onboard computer, a tablet computer, etc. For example, the user device 1004(1) is illustrated as a desktop computer, while the user device 1004(N) is illustrated as an example of a handheld mobile device.

The user device 1004 may include a memory 1014 and processor(s) 1016. In the memory 1014 may be stored program instructions that are loadable and executable on the processor(s) 1016, as well as data generated during the execution of these programs. Depending on the configuration and type of user device 1004, the memory 1014 may be volatile (such as random access memory (“RAM”)) and/or non-volatile (such as read-only memory (ROM), flash memory, etc.).

In some examples, the memory 1014 may include a version of an iterative algorithm 130 (e.g., iterative algorithm 130(1)). The iterative algorithm 130(1) may allow the user 1006 to interact with the computer system 1002 via the network 1008. The user device 1004 may also include one or more interfaces 1018 to enable communication with other devices, systems, and the like. The iterative algorithm 130(1), whether embodied in the user device 1004 or the computer system 1002, may be configured to perform the techniques described herein. For example, the iterative algorithm 130(1) can be configured to generate recommended design parameters for a robotic manipulator by minimizing an objective function subject to constraints. In an example, the iterative algorithm 130(1) can include any other suitable devices, engines, modules, models, and the like.

Turning now to the details of the computer system 1002, the computer system 1002 may include one or more computer system computers, perhaps arranged in a cluster of servers or as a server farm, and may host web service applications. The function of the computer system 1002 may be implemented a cloud-based environment such that individual components of the computer system 1002 are virtual resources in a distributed environment.

The computer system 1002 may include at least one memory 1020 and one or more processing units (or processor(s)) 1022. The processor 1022 may be implemented as appropriate in hardware, computer-executable instructions, software, firmware, or combinations thereof. Computer-executable instruction, software, or firmware implementations of the processor 1022 may include computer-executable or machine-executable instructions written in any suitable programming language to perform the various functions described. The memory 1020 may include more than one memory and may be distributed throughout the computer system 1002. The memory 1020 may store program instructions that are loadable and executable on the processor(s) 1022, as well as data generated during the execution of these programs. Depending on the configuration and type of memory including the computer system 1002, the memory 1020 may be volatile (such as RAM and/or non-volatile (such as read-only memory (“ROM”), flash memory, or other memory)). The memory 1020 may include an operating system 1024 and one or more application programs, modules, or services for implementing the features disclosed herein including at least a version of the iterative algorithm 130 (e.g., 130(2)). For example, the iterative algorithm 130(2) may perform the functionality described herein.

The computer system 1002 may also include additional storage 1028, which may be removable storage and/or non-removable storage including, but not limited to, magnetic storage, optical disks, and/or tape storage. The disk drives and their associated computer-readable media may provide non-volatile storage of computer-readable instructions, data structures, program modules, and other data for the computing devices. The additional storage 1028, both removable and non-removable, is an example of computer-readable storage media. For example, computer-readable storage media may include volatile or non-volatile, removable, or non-removable media implemented in any suitable method or technology for storage of information such as computer-readable instructions, data structures, program modules, or other data. As used herein, modules, engines, applications, and components may refer to programming modules executed by computing systems (e.g., processors) that are part of the computer system 1002 and/or part of the computer system 106.

The computer system 1002 may also include input/output (I/O) device(s) and/or ports 1030, such as for enabling connection with a keyboard, a mouse, a pen, a voice input device, a touch input device, a display, speakers, a printer, or other I/O device.

In some examples, the computer system 1002 may also include one or more user interface(s) 1032. The user interface 1032 may be utilized by an operator, curator, or other authorized user to access portions of the computer system 1002. In some examples, the user interface 1032 may include a graphical user interface, voice interfaces, web-based applications, programmatic interfaces such as APIs, or other user interface configurations.

The computer system 1002 may also include a data store 1001. In some examples, the data store 1001 may include one or more databases, data structures, or the like for storing and/or retaining information associated with the computer system 1002. The iterative algorithm 130 is communicatively coupled (e.g., via a wired connection or a wireless connection) to the data store 1001. The data store 1001 includes a design parameter storage 1034. In an example, the data store 1001 can include any other suitable data, databases, libraries, and the like.

The specification and drawings are, accordingly, to be regarded in an illustrative rather than a restrictive sense. It will, however, be evident that various modifications and changes may be made thereunto without departing from the broader spirit and scope of the disclosure as set forth in the claims.

Other variations are within the spirit of the present disclosure. Thus, while the disclosed techniques are susceptible to various modifications and alternative constructions, certain illustrated embodiments thereof are shown in the drawings and have been described above in detail. It should be understood, however, that there is no intention to limit the disclosure to the specific form or forms disclosed, but on the contrary, the intention is to cover all modifications, alternative constructions, and equivalents falling within the spirit and scope of the disclosure, as defined in the appended claims.

The use of the terms “a” and “an” and “the” and similar referents in the context of

describing the disclosed embodiments (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. The term “connected” is to be construed as partly or wholly contained within, attached to, or joined together, even if there is something intervening. Recitation of ranges of values herein are merely intended to serve as a shorthand method of referring individually to each separate value falling within the range, unless otherwise indicated herein and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate embodiments of the disclosure and does not pose a limitation on the scope of the disclosure unless otherwise claimed. No language in the specification should be construed as indicating any non-claimed element as essential to the practice of the disclosure.

Disjunctive language such as the phrase “at least one of X, Y, or Z,” unless specifically stated otherwise, is intended to be understood within the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present.

Preferred embodiments of this disclosure are described herein, including the best mode known to the inventors for carrying out the disclosure. Variations of those preferred embodiments may become apparent to those of ordinary skill in the art upon reading the foregoing description. The inventors expect skilled artisans to employ such variations as appropriate and the inventors intend for the disclosure to be practiced otherwise than as specifically described herein. Accordingly, this disclosure includes all modifications and equivalents of the subject matter recited in the claims appended hereto as permitted by applicable law. Moreover, any combination of the above-described elements in all possible variations thereof is encompassed by the disclosure unless otherwise indicated herein or otherwise clearly contradicted by context.

All references, including publications, patent applications, and patents, cited herein are hereby incorporated by reference to the same extent as if each reference were individually and specifically indicated to be incorporated by reference and were set forth in its entirety herein.

What is claimed is:

1. A computer system, comprising:
a processing device; and
a non-transitory memory configured to store instructions that are executable by the processing device for causing the processing device to at least:
receive a first configuration of design parameters for a robotic arm, the design parameters comprising one or more discrete hardware parameters and one or more continuous hardware parameters;
set one or more constraints comprising (i) a waypoint through which an end effector of the robotic arm travels to reach a second set of positions of a particular task and (ii) a set of points associated with an obstacle through which the end effector does not travel to reach the second set of positions, wherein the particular task involves moving an object using the end effector from any of a first set of positions to any of the second set of positions; and
generate, using an iterative algorithm and based at least in part on the first configuration of design parameters, (i) a second configuration of design parameters for the robotic arm and (ii) a trajectory associated with the second configuration for moving the object from any of the first set of positions to any of the second set of positions by minimizing an objective function subject to the one or more constraints, wherein the trajectory intersects the waypoint and does not intersect the set of points associated with the obstacle.

2. The computer system of claim 1, wherein the objective function comprises a cycle time for the robotic arm to move the object from one of the first set of positions to one of the second set of positions along the trajectory.

3. The computer system of claim 1, wherein the one or more discrete hardware parameters comprise at least one of a number of joints, a joint type, or an actuator size for the robotic arm, and wherein the one or more continuous hardware parameters comprise at least one of a segment length, a mounting angle, or a base location for the robotic arm.

4. The computer system of claim 1, wherein the one or more constraints further comprise a torque limit for one or more joints for the robotic arm, and wherein the objective function comprises a torque on the one or more joints when performing the particular task or a maximum velocity of the one or more joints when performing the particular task.

5. A computer-implemented method, comprising:
receiving a first configuration of design parameters for a component of a robotic manipulator, wherein the design parameters comprise one or more discrete hardware parameters;
setting one or more constraints comprising a waypoint through which the robotic manipulator travels to reach a second position for a particular task involving manipulating an object between a set of positions including a first position and the second position; and
generating, using an iterative algorithm and based at least in part on the first configuration of design parameters, (i) a second configuration of design parameters for the component of the robotic manipulator and (ii) a trajectory associated with the second configuration for performing the particular task between the set of positions by minimizing an objective function subject to the one or more constraints.

6. The computer-implemented method of claim 5, wherein generating, by the iterative algorithm, the second configuration of design parameters and the trajectory further comprises:
generating a set of adjusted design parameters that satisfy the one or more constraints by iterating on the first configuration of design parameters;
determining a value for the objective function for each of the set of adjusted design parameters to generate a set of values; and
selecting the second configuration of design parameters by identifying an adjusted design parameter of the adjusted design parameters associated with a minimum value from the set of values.

7. The computer-implemented method of claim 5, wherein the design parameters further comprise one or more continuous hardware parameters.

8. The computer-implemented method of claim 5, wherein the one or more constraints further comprises a set of points associated with an obstacle through which the robotic manipulator is prevented from travelling, wherein the trajectory does not intersect with the set of points associated with the obstacle.

9. The computer-implemented method of claim 5, wherein the one or more constraints comprise a torque limit for one or more joints of the robotic manipulator, and wherein the objective function comprises a sum of squared torques on the one or more joints when performing the particular task.

10. The computer-implemented method of claim 5, wherein the design parameters comprise at least one of a type of joint comprising a revolute joint or a prismatic joint, a number of joints, a segment length between adjacent joints, or a joint mounting angle for the robotic manipulator.

11. The computer-implemented method of claim 5, wherein the one or more constraints further comprise at least one of a maximum velocity and a maximum acceleration for the robotic manipulator performing the particular task along the trajectory.

12. The computer-implemented method of claim 5, wherein the one or more constraints further comprise an end velocity and an end acceleration of zero at an end point of the trajectory.

13. The computer-implemented method of claim 5, wherein generating the second configuration of design parameters further comprises:
generating a set of adjusted design parameters by iterating on the first configuration of design parameters;
for each design parameter of the set of adjusted design parameters, determining a value of the objective function based on each combination of a start point of a range of start points in the set of positions and an end point of a range of end points in the set of positions for the robotic manipulator performing the particular task to generate a set of values of the objective function; and
selecting the second configuration of design parameters from the set of adjusted design parameters based on the set of values.

14. The computer-implemented method of claim 13, wherein selecting the second configuration of design parameters from the set of adjusted design parameters further comprises:
determining, for each design parameter of the set of adjusted design parameters, an average value of the set of values for the objective function; and
determining that the second configuration of design parameters is associated with a lowest average value for the objective function of the set of adjusted design parameters.

15. The computer-implemented method of claim 13, wherein generating the second configuration of design parameters further comprises:
for each design parameter of the set of adjusted design parameters, determining the value of the objective function based on each mass of a set of masses for the object to generate the set of values of the objective function; and
determining that the second configuration of design parameters is associated with a lowest average value for the objective function of the set of adjusted design parameters.

16. The computer-implemented method of claim 5, wherein the iterative algorithm is configured to generate the second configuration of design parameters simultaneously with the trajectory.

17. One or more non-transitory computer-readable media comprising computer-executable instructions that, when executed by one or more processing devices of a computer system, cause the computer system to perform operations comprising:
receiving a first configuration of design parameters for a robotic manipulator, wherein the design parameters comprise one or more discrete hardware parameters;
setting one or more constraints comprising a waypoint through which the robotic manipulator travels to reach a second position for a particular task involving manipulating an object between a set of positions including a first position and the second position; and
generating, using an iterative algorithm and based at least in part on the first configuration of design parameters, (i) a second configuration of design parameters for the robotic manipulator and (ii) a trajectory associated with the second configuration for performing the particular task between the set of positions by minimizing an objective function subject to the one or more constraints.

18. The one or more non-transitory computer-readable media of claim 17, wherein the objective function comprises a cycle time for the robotic manipulator to move the object from a start point to an end point along the trajectory.

19. The one or more non-transitory computer-readable media of claim 17, wherein the one or more constraints further comprise a torque limit for one or more joints of the robotic manipulator, and wherein the objective function comprises a sum of squared torques on the one or more joints when performing the particular task.

20. The one or more non-transitory computer-readable media of claim 17, wherein the one or more discrete parameters comprise at least one of a number of joints, a joint type, or an actuator size for the robotic manipulator.
